(19) United States
(12) Patent Application Publication
(10) Pub. No.: US 2003/0153141 A1
(43) Pub. Date: Aug. 14, 2003

(54) Screen printable electrode for light emitting polymer device

(76) Inventors: Susan A. Carter, Santa Cruz, CA (US); John G. Victor, Chicago, IL (US)

Correspondence Address: PILLSBURY WINTHROP LLP, 1600 Tysons Boulevard, McLean, VA, 22102, US

(21) Appl. No.: 10/327,632

(22) Filed: Dec. 20, 2002

Related U.S. Application Data
(60) Provisional application No. 60/342,579, filed on Dec. 20, 2001.

(51) Int. Cl. H01L 21/8238

(52) U.S. Cl. 438/200

(57) ABSTRACT

A screen printed light emitting polymer device is fabricated by depositing an electroluminescent polymer layer between a transparent electrode and an air stable screen printed top electrode. Screen printing a conductive electrode on top of a light emitting polymer layer typically results in a short circuit because metal conductive particles poke through the polymer layer. We have found three ways to prevent this. One is to screen print an organic conductor on top of the light emitting polymer layer so that metal conductive particles cannot penetrate to the transparent electrode. Another way is to decrease the particle size in the conductive metal paste in addition to using a solvent that does not soften the light emitting polymer layer being printed on. A third way is to print a sol-gel conductive layer where the conductive metal particles precipitate after the layer is printed. In addition, additives to the screen printed top electrode can be used to improve device efficiency.

### PRIORITY CLAIM

The present application claims priority benefit from U.S. Provisional Patent Application No. 60/342,579 filed Dec. 20, 2001 and entitled “Screen Printable Electrode for Light Emitting Polymer Device”, the contents of which are incorporated herein by reference.

### FIELD OF THE INVENTION

The present invention relates to electroluminescent devices, and more particularly to the fabrication of electroluminescent devices.

### BACKGROUND OF THE INVENTION

Light-emitting polymer (LEP) devices have been under development for back-lighting in liquid crystal displays and instrument panels, and to replace vacuum fluorescent and liquid crystal displays. There are several patents (see references 1-3) that teach how different LEP device layers enable the efficient production of electroluminescent light. For instance, U.S. Pat. No. 6,284,435 to Cao discloses electrically active polymer compositions and their use in efficient, low operating voltage, polymer light-emitting diodes with air-stable cathodes. Additionally, U.S. Pat. No. 5,399,502 to Friend et al. shows a method of manufacturing electroluminescent devices. Finally, U.S. Pat. No. 5,869,350 to Heeger et al. demonstrates the fabrication of visible light emitting diodes soluble semiconducting polymers.

Screen printing is a cost-effective fabrication technique that can be used to deposit most of the layers of LEP's through patterned mask screens. In commonly owned U.S. patent application Ser. No. 09/844,703 to Victor et al., novel screen printing techniques for light-emitting polymer devices are disclosed. The screen printing technique allows large areas to be printed with complex, patterned detail. One layer, the top electrode, has not previously been screen printable (i.e. via liquid processes under atmospheric conditions) which greatly increases the complexity and cost of fabricating LEP devices. To complete a circuit that allows electroluminescence requires two electrodes. At least one of the two electrodes, the one on the viewing surface, is transparent to allow light created in the LEP layer(s) to escape, thereby producing light external to the device.

FIG. 1 illustrates a forward-build of a particular kind of LEP device called a light emitting diode, or LED. The direction-of-build construction refers to the sequence in which the LEP layers are deposited in relation to the direction of emitted light. As shown in FIG. 1, the forward-build construction starts with the transparent electrode adjacent to the bottom substrate, with the direction of emitted light being from top to bottom.

FIG. 2 illustrates a reverse-build construction of an LED. As shown in FIG. 2, the reverse-build construction is the sequence in which layers are deposited starting with an non-transparent electrode adjacent to, or even comprised within, the bottom substrate, with the direction of emitted light being from bottom to top. This non-transparent electrode may or may not be patterned.

These LED-type of device structures, as shown in FIGS. 1 and 2, require the most amount of layers for fabrication by screen printing. As shown, both types require up to six different layers on top of the bottom substrate. By contrast, FIG. 3 illustrates a forward-build LEP device structure. As shown in FIG. 3, a preferred forward-build LEP device can consist of as few as three patterned layers on top of the bottom substrate.

Several barriers exist for screen printing the top electrode of the LEP device as in FIG. 3. Efficient LEP operation normally requires very thin films of less than 100 nm for the emissive polymer layer, as well as the charge transport layers. Screen printing an electrode on top of such soft thin films invariably leads to shorting and device failure. These effects are compounded by the solvents used for the printable electrodes that can lead to softening or dissolution of the light emitting polymer layer.

Moreover, efficient electron injection into the light emitting polymer layer requires a metal with a low work-function, such as Calcium. However, low work-function metals readily oxidized upon exposure to air. As a consequence, top electrodes that are cathodes, as shown in forward-build devices of FIGS. 1 and 3, have typically been deposited using vacuum-based processing, such as thermal evaporation or RF sputtering. Heretofore, top cathodes for forward-build LEP devices have not been screen printable. Whichever LEP construction is selected, forward- or reverse-build, it is desirable for ease of fabrication and low cost to screen print as many layers as possible, including the top electrode.

A variety of screen printable conductive pastes are commercially available. The most conductive pastes include silver in a polymer matrix containing enough solvent to make a viscous paste that can be printed as a flat layer through a screen, which is typically of polyester cloth patterned with a photo-emulsion. The silver particles in these conductive pastes are usually flat flakes or spheres averaging 10 or more microns in diameter. Other less conductive pastes, typically used for special applications, require nickel flakes, carbon particles or antimony-doped tin oxides as the conductive particle.

In addition to these inorganic conductive pastes, screen-printable electrically conducting organic polymer pastes are also commercially available, such as PSS-PEDOT (from Bayer, Agfa) and polyaniline. These organic polymer conductive pastes do not have as high of an electrical conductivity as the higher conductivity inorganic metal conductive pastes. Their lower conductivity restricts their applicability in LEP devices, which have a relatively high electrical current requirements. The low conductivity of the organic pastes can cause a significant voltage drop between the power supply and the LEP light emitting element, producing an LEP device with non-uniform brightness. This non-uniformity in brightness imposes a severe design constraint, especially for larger area format devices.

A final class of conductive inks are conductive sol-gels, in which conductive particles precipitate from solution in a porous gel network. After being screen printed, the sol-gel layer is dried at moderate temperature forming a rigid film. Some films made from sol-gels are compliant and densify during drying, allowing the precipitated conductive particles to come into partial contact to impart electrical conductivity.

Several methods exist for printing conductive pastes under atmospheric conditions, such as ink-jet, reel-to-reel, flexography and screen printing. Typically, when a conductive paste is screen printed, the paste is first distributed on top of the patterned screen by a floodbar so that it fills in the openings of the open pattern area in the cloth. Next, a squeegee edge moves above the screen, pressing down so that it forces out the paste in the open pattern onto the substrate beneath. This creates individual, tiny pillars of ink that flatten and flow on the substrate so that they connect. Once the paste dries, a continuous conductive layer is created.

Typically, when attempting to screen print a high conductivity paste, such as a silver paste, as the top electrode to an LEP device, the silver particles frequently push through the thin LEP emission layer by the action of the squeegee. This silver particle push-through causes shorts between the electrodes when voltage is applied to the device, which leads to device failure or ineffective device operation.

Moreover, screen printing of the top electrode is done under atmospheric conditions. This typically limits the selection of conductive paste metals to those with a relatively high work-function, which attempts to avoid electrode degradation due to oxidation upon exposure to air. However, high work function metals do not normally allow for efficient device operation in LEP structures because of their lack of efficient electron injection into the emissive polymer layer.

Therefore, what is needed is a process that allows for the deposition of a screen printable conductive paste on top of the device structure under atmospheric conditions that will not detrimentally affect device performance (i.e. due to shorting, dissolution of bottom layer(s), or electrode oxidation) and still allow for efficient device operation.

### SUMMARY OF THE INVENTION

The present invention discloses the important process step of screen printing the top electrode in LEP device construction under normal atmospheric conditions. This process step is critical in the inexpensive fabrication of electroluminescent devices with light-emitting organic materials since it allows all layers to be patterned by a screen printing process.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a diagram of a forward-build polymer LED device;

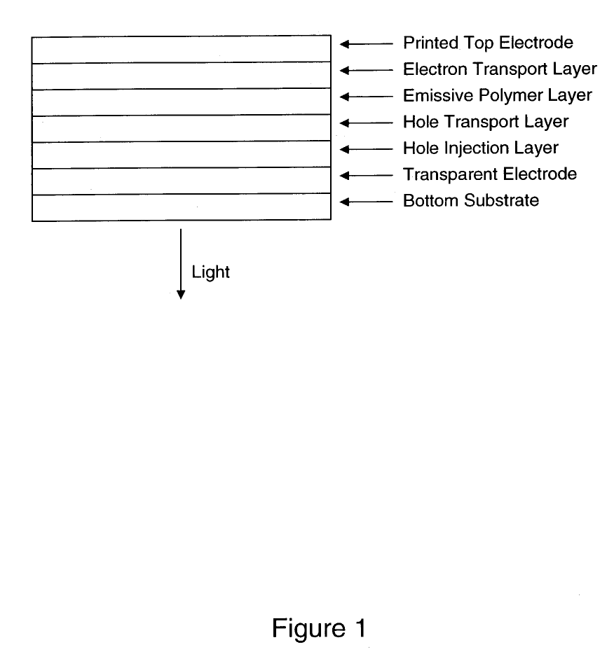

FIG. 2 is a diagram of a reverse-build polymer LED device;

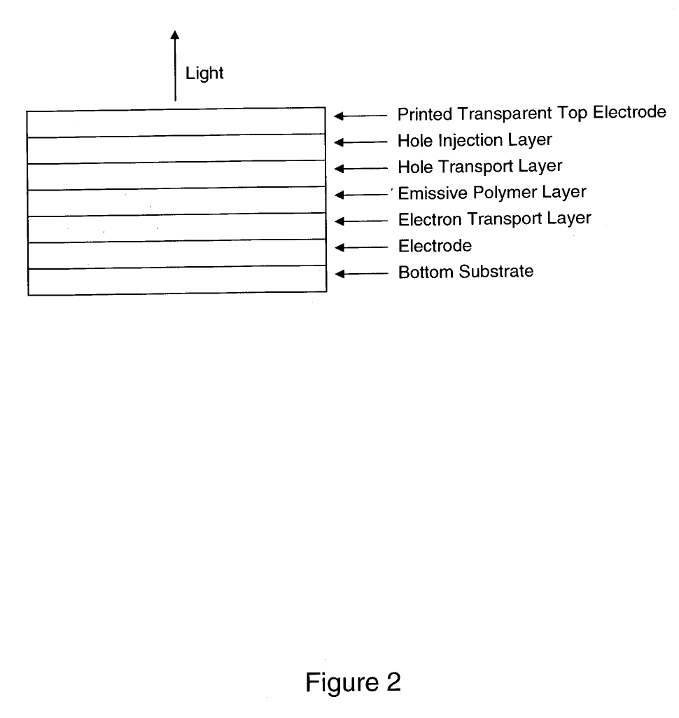

FIG. 3 is a diagram of a forward-build simplified polymer LEP device, and

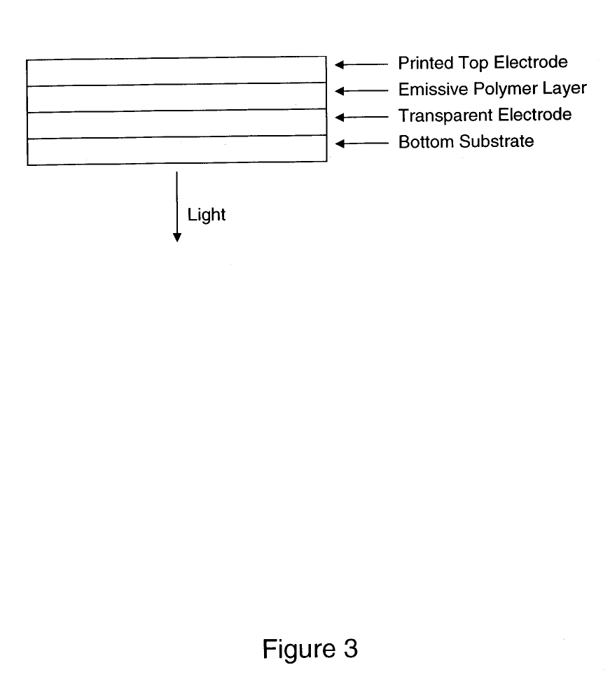

FIG. 4 shows the device performance of a fully screen printed LEP device.

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention. Moreover, where certain elements of the present invention can be partially or fully implemented using known components, only those portions of such known components that are necessary for an understanding of the present invention will be described, and detailed descriptions of other portions of such known components will be omitted so as not to obscure the invention. Further, the present invention encompasses present and future known equivalents to the known components referred to herein by way of illustration.

The present invention includes three methods to screen print a top electrode that avoids shorts in LEP devices.

In one embodiment of the present invention, a charge transporting or conducting polymer layer is screen printed onto the light emitting polymer layer prior to screen printing the top electrode paste. This adds a thick conductive buffer layer between the printed top electrode and the emissive layer so that a commercial silver paste can be used as for printing the top electrode without creating hard shorts. This charge transporting or conducting polymer layer should be too soft to short through the emission layer and should be chosen so that the solvent in the conducting polymer does not soften or crack the light emissive layer.

Another embodiment of the present invention involves decreasing the particle size of the conductive particles in the conducting paste, and alter the conductive particle morphology so that penetration of the conductive particles through the emissive layer is suppressed. The conductive particles of this embodiment should consist of flattened shapes (i.e., flakes) that are between 5 nanometers and 30 microns in diameter, which are less likely to short than spherically shaped particles. In this embodiment, the solvent in the conducting inorganic paste cannot soften or crack the light emitting layer polymer on which it is printed. This embodiment also involves controlling or modifying the solvent for the conducting paste so that the solvent does not detrimentally affect the bottom layers or promote short formation. Solvents that work well for this embodiment include, but are not limited to, dibasic esters.

In a third embodiment of the present invention, a sol-gel charge transport or conductive layer is screen printed. This adds a thick conductive buffer layer between the printed top electrode and the emissive layer so that a commercial silver paste can be used as for printing the top electrode without creating hard shorts. Like the conductive polymer discussed above, the sol-gel is so soft that it can be screen printed on the underlying layer without causing hard shorts. Also like the conductive polymer discussed above, the solvent associated with the sol-gel should not soften or crack the underlying emissive polymer layer. Sol-gel materials that work well and facilitate charge injection for this embodiment include, but are not limited to, titanium oxide and related sol-gel materials.

To achieve efficient charge injection from the printed top electrode into the LEP device, further modifications must be made to either the electroluminescent polymer ink, the formulation of the printable top electrode paste, or to both the ink and paste. In the electroluminescent polymer ink, as described in commonly owned U.S. patent application Ser. No. 10/___,___ (filed: Dec. 20, 2002, Atty Dkt: 015126-0300678, Client Ref. AVI-7220), dopants can be added that are effective in promoting efficient device operation so that further changes to the formulation of the electrode paste (other than those previously described, above) are not necessarily needed. However, an embodiment of the present invention includes three possible additions to the top electrode paste that enable more efficient charge injection in the absence of additional dopants to the electroluminescent polymer ink.

In one aspect of this embodiment, an inorganic coating is added directly to the printable top electrode particles to improve charge injection. Such inorganic coating materials must be relatively stable in air and during the encapsulation process so they do not degrade device performance during its lifetime. Coating materials meeting the criteria of this aspect include, but are not limited to, a material such as Lithium Fluoride (LiF) and related monovalent and divalent ionic materials.

In a second aspect of this embodiment, an inorganic or organic salt or surfactant is directly added to the printable top electrode paste to improve charge injection. This involves using a salt or surfactant that is relatively stable upon exposure to air, temperatures up to 130 degrees Celsius, and during the encapsulation process. The salt or surfactant should also be soluble in the top electrode paste.

Salts meeting the criteria of this aspect of the invention include materials that are less reactive and less mobile than materials consisting of monovalent and, in some cases, divalent cations. The salt may have: a cation that is a singly ionized alkali metal, such as lithium, sodium, potassium or cesium; a cation that is an ion of a metal, such as calcium, barium or aluminum; or an organic cation, such as tetrabutyl ammonium, tetraethyl ammonium, tetrapropyl ammonium, tetramethyl ammonium, or phenyl ammonium. The salt may also have: an inorganic ion that includes singly ionized halogens, such as fluorine, chlorine, bromine or iodine; an inorganic anion, such as sulfate, tetrafluoroborate, hexafluorophosphate, or aluminum tetrachlorate; or an organic anion, such as trifluormethane sulfonate, trifluroacetate, tetraphenylborate, or toluene sulfonate. Quantities are added from about 1% to 10% by weight.

A second aspect of this embodiment is to blend a charge transporting organic material, normally a polymer, into the printable top electrode paste. Such a charge transporting organic material will normally have relative energy levels that facilitate electron injection into the LEP device. When the top electrode operates as a cathode, the charge transporting material should be an electron transporting material chosen with a LUMO (lowest unoccupied molecular orbital) lying in energy between the LUMO of the LEP and the work function of the cathode. When the top electrode operates as an anode, the charge transporting material should be a hole transporting material chosen with a HOMO (highest occupied molecular orbita) lying in energy between the HOMO of the LEP and the work function of the anode. The charge transporting material should be relatively stable upon exposure to air, temperatures up to 130 degrees Celsius, and during the encapsulation process. The material should be added in sufficiently small concentrations so as not to increase the resistivity of the printed top electrode above about 10,000 ohms/square. Quantities are added from about 5% to 50% by weight.

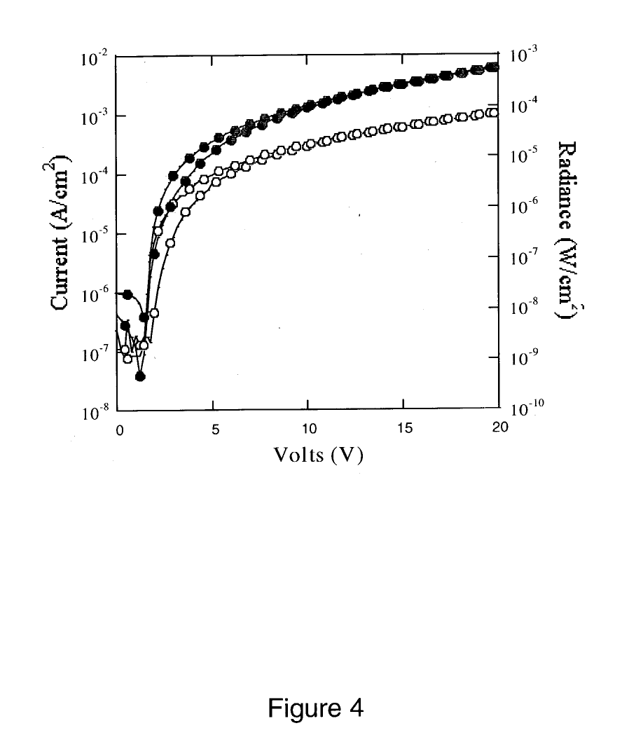

One example of the present invention in use is now provided, and consists of an LEP device with a screen printed, doped, emissive polymer layer and a top electrode made of a screen printable silver conductive paste. In this example, a commercially available screen printable silver conductive flake paste from Conductive Compounds is modified to remove one of the solvents that is detrimental to LEP performance. This modified conductive paste is screen printed onto the emissive polymer layer, doped to contain MEH-PPV, PEO, and tetrabutylammonium sulfate, through a 230 mesh plain-weave polyester cloth with 48 micron thread diameter. After drying the printed conductive paste at 125° C. for 5 minutes, it forms a highly conductive top electrode capable of supplying current to the LEP device over areas as large as several square inches, without hard shorts. Device performance is shown in FIG. 4.

Another example of the present invention in use is also provided, and consists of an LEP device with a screen printed emissive polymer layer and a top electrode made of a screen printable, doped, silver conductive paste. In this example, a commercially available screen printable silver conductive flake paste from Conductive Compounds is modified to remove one of the solvents that is dissolves the emissive polymer layer. Additionally, tetrybutylammonium-tetraflouroborate is added to this silver paste at a weight ratio of about 1 part in 1000. This doped conductive paste is screen printed onto the emissive polymer layer through a 230 mesh plain-weave polyester cloth with 48 micron thread diameter. After drying at 125° C. for 5 minutes the doped conductive paste forms a highly conductive top electrode capable of supplying current to the LEP device over areas as large as several square inches, without hard shorts.

Although the present invention has been particularly described with reference to the preferred embodiments thereof, it should be readily apparent to those of ordinary skill in the art that changes and modifications in the form and details thereof may be made without departing from the spirit and scope of the invention. For example, those skilled in the art will understand that variations can be made in the number and arrangement of components illustrated in the above block diagrams. It is intended that the appended claims include such changes and modifications.

What is claimed is:

1. An electroluminescent device comprising a plurality of layers, wherein the plurality of layers includes:
a bottom electrode layer;
a light-emitting material layer, the light-emitting material layer being created over the bottom electrode layer; and
a top electrode layer, the top electrode layer being printed under atmospheric conditions over the light-emitting material layer.

2. The device according to claim 1, wherein the light-emitting material layer contains a conjugated polymer.

3. The device according to claim 1, wherein the light-emitting material layer contains a light-emitting organic molecule.

4. The device according to claim 1, wherein the top electrode layer is screen printed.

5. The device according to claim 4, wherein the top electrode layer is a screen printable conducting paste.

6. The device according to claim 1, wherein the top electrode layer is ink-jet printed.

7. The device according to claim 1, wherein the top electrode layer is roll process printed.

8. The device according to claim 1, wherein the top electrode layer is web-based process printed.

9. The device according to claim 1, wherein the top electrode layer is flexography-based process printed.

10. The device according to claim 5, wherein the screen printable conducting paste includes particles selected from the group consisting of silver, carbon, nickel, composite metal, and conducting metal oxide.

11. The device according to claim 10, wherein the particles are between about 5 nanometers and 30 microns in diameter.

12. The device according to claim 10, wherein the particles are a flattened shape.

13. The device according to claim 5, wherein the screen printable conducting paste further includes a soluble polymer.

14. The device according to claim 13, wherein the soluble polymer is a charge transporting polymer.

15. The device according to claim 14, wherein the charge transporting polymer is poly(3,4-ethylene dioxythiophene)-poly(styrenesulphonate) (PEDOT-PSS), polyaniline (PAni), or triphenylamine.

16. The device according to claim 5, wherein the screen printable conducting paste includes a solvent.

17. The device according to claim 16, wherein the solvent does not substantially dissolve the light-emitting material layer.

18. The device according to claim 16, wherein the solvent is ester-based.

19. The device according to claim 5, wherein the screen printable conducting paste includes at least one of an ionic dopant and a salt.

20. The device according to claim 19, wherein the salt has a cation that is a singly ionized alkali metal.

21. The device according to claim 20, wherein the salt is lithium, sodium, potassium or cesium.

22. The device according to claim 19, wherein the salt has a cation that is an ion of a metal.

23. The device according to claim 22, wherein the salt is calcium, barium, or aluminum.

24. The device according to claim 19, wherein the salt has an organic cation.

25. The device according to claim 24, wherein the salt is tetrabutyl ammonium, tetraethyl ammonium, tetrapropyl ammonium, tetramethyl ammonium, or phenyl ammonium.

26. The device according to claim 19, wherein the salt has an inorganic ion that includes a singly ionized halogen.

27. The device according to claim 26, wherein the salt is fluorine, chlorine, bromine, or iodine.

28. The device according to claim 19, wherein the salt has an inorganic anion.

29. The device according to claim 28, wherein the salt is sulfates tetrafluoroborate, hexafluorophosphate, or aluminum tetrachlorate.

30. The device according to claim 19, wherein the salt has an organic anion.

31. The device according to claim 30, wherein the salt is trifluormethane sulfonate, trifluoroacetate, tetraphenylborate, or toluene sulfonate.

32. The device according to claim 19, wherein the top electrode layer includes an ionic surfactant.

33. The device according to claim 1, wherein the top electrode layer includes a conducting sol-gel.

34. The device according to claim 33, wherein the conducting sol-gel includes doped tin oxide.

35. The device according to claim 33, wherein the conducting sol-gel includes at least one of an ionic dopant and a salt.

36. The device according to claim 1, wherein the top electrode layer includes a conducting polymer.

37. The device according to claim 36, wherein the conducting polymer is poly(3,4-ethylene dioxythiophene)-poly(styrenesulphonate) (PEDOT-PSS), or polyaniline (PAni).

38. The device according to claim 1, wherein the top electrode layer includes a charge transporting polymer.

39. The device according to claim 38, wherein the charge transporting polymer is poly(3,4-ethylene dioxythiophene)-poly(styrenesulphonate) (PEDOT-PSS), polyaniline (PAni), or triphenylamine.

40. The device according to claim 1, wherein the top electrode layer includes an ionic surfactant.

41. The device according to claim 1, wherein the top electrode layer includes at least one of an ionic dopant and a salt.

42. The device according to claim 41, wherein the salt has a cation that is a singly ionized alkali metal.

43. The device according to claim 42, wherein the salt is lithium, sodium, potassium, or cesium.

44. The device according to claim 41, wherein the salt has a cation that is an ion of a metal.

45. The device according to claim 44, wherein the salt is calcium, barium, or aluminum.

46. The device according to claim 41, wherein the salt has an organic cation.

47. The device according to claim 46, wherein the salt is tetrabutyl ammonium, tetraethyl ammonium, tetrapropyl ammonium, tetramethyl ammonium, or phenyl ammonium.

48. The device according to claim 41, wherein the salt has an inorganic anion that includes singly inonized halogen.

49. The device according to claim 48, wherein the salt is fluorine, chlorine, bromine, or iodine.

50. The device according to claim 41, wherein the salt has an inorganic anion.

51. The device according to claim 50, wherein the salt is sulfate, tetrafluoroborate, hexafluorophosphate, or aluminum tetrachlorate.

52. The device according to claim 41, wherein the salt has an organic anion.

53. The device according to claim 52, wherein the salt is trifluormethane sulfonate, trifluoroacetate, tetraphenylborate, or toluene sulfonate.

54. The device according to claim 1, wherein the plurality of layers further includes a charge transporting layer, the charge transporting layer being printed over the light-emitting material layer and below the top electrode layer.

55. The device according to claim 54, wherein the charge transporting layer is a conjugated polymer.

56. The device according to claim 54, wherein the charge transporting layer is a sol-gel.

57. The device according to claim 54, wherein the charge transporting layer includes at least one of an ionic dopant or a salt.

58. The device according to claim 54, wherein the charge transporting layer includes an ionic surfactant.

59. The device according to claim 1, wherein the bottom electrode layer is below and adjacent to the light-emitting material layer, and the top electrode is above and adjacent to the light-emitting material layer.

60. A method of making an electroluminescent device that includes a plurality of layers, the steps comprising:
creating a bottom electrode layer;
creating a light-emitting material layer, the light-emitting material layer being created over the bottom electrode layer; and
printing a top electrode layer, the top electrode layer being printed under atmospheric conditions over the light-emitting material layer.

61. The method according to claim 60, wherein the top electrode layer is screen printed.

62. The method according to claim 60, wherein the top electrode layer is a screen printable conducting paste.

63. The method according to claim 60, wherein the top electrode layer is ink-jet printed.

64. The method according to claim 60, wherein the top electrode layer is roll process printed.

65. The method according to claim 60, wherein the top electrode layer is web-based process printed.

66. The method according to claim 60, wherein the top electrode layer is flexography-based process printed.

67. The method according to claim 60, wherein the top electrode layer includes a conducting sol-gel.

68. The method according to claim 60, wherein the top electrode layer includes a conducting polymer.

69. The method according to claim 60, wherein the top electrode layer includes a charge transporting polymer.

70. The method according to claim 60, wherein the top electrode layer includes an ionic surfactant.

71. The method according to claim 60, wherein the top electrode layer includes at least one of an ionic dopant and a salt.

72. The method according to claim 60, further comprising the step of printing a charge transporting layer, the charge transporting layer being printed over the light-emitting material layer and below the top electrode layer.
